(19) United States
(12) Patent Application Publication
(10) Pub. No.: US 2014/0159100 A1
(43) Pub. Date: Jun. 12, 2014

(54) PATTERNED SUBSTRATE AND ELECTRO-OPTICAL SEMICONDUCTOR ELEMENT

(71) Applicant: Lucemitek Co., Ltd., Taoyuan County (TW)

(72) Inventors: Cheng-Yu CHIU, Zhongli City (TW); Chun-Yi LEE, Zhongli City (TW); Chun-Hung CHEN, Zhongli City (TW); Chih-An CHEN, Zhongli City (TW); Wei-Lun WANG, Zhongli City (TW)

(73) Assignee: Lucemitek Co., Ltd., Taoyuan County (TW)

(21) Appl. No.: 14/103,843

(22) Filed: Dec. 11, 2013

(30) Foreign Application Priority Data
Dec. 12, 2012 (TW) 101146961

(51) Int. Cl. H01L 31/0224; H01L 33/38

(52) U.S. Cl. CPC H01L 31/0224; H01L 33/38
USPC 257/99; 257/459

(57) ABSTRACT

A patterned substrate comprises a substrate body and a plurality of solid patterns disposed on the substrate body. The pitch of at least a part of the adjacent solid patterns is between 1.5 μm and 2.5 μm, the space of at least a part of the adjacent solid patterns is between 0.1 μm and 0.7 μm, and the height of at least a part of the solid patterns is between 0.7 μm and 1.7 μm. An electro-optical semiconductor element containing the patterned substrate is also disclosed.

### CROSS REFERENCE TO RELATED APPLICATIONS

This Non-provisional application claims priority under 35 U.S.C. §119(a) on Patent Application No(s). 101146961 filed in Taiwan, Republic of China on Dec. 12, 2012, the entire contents of which are hereby incorporated by reference.

### BACKGROUND OF THE INVENTION

1. Field of Invention

The invention relates to an electro-optical semiconductor element and, in particular, to an electro-optical semiconductor element with enhanced electro-optical efficiency.

2. Related Art

The electro-optical semiconductor element has been widely applied to various fields, such as illumination, vehicles, display apparatuses, communication industry and computers.

A conventional electro-optical semiconductor element includes a substrate body and a plurality of solid patterns disposed on a surface of the substrate body. The solid patterns are arranged into a row regularly, so the substrate is regarded as a patterned structural substrate (PSS) and also called a patterned substrate.

FIG. 1A is a partial top view of a conventional patterned substrate, and FIG. 1B is a schematic diagram of a plurality of conventional solid patterns. As shown in FIGS. 1A and 1B, the patterned substrate 10 includes a substrate body 11 and a plurality of solid patterns 12. Each of the solid patterns 12 is a regular conoid, and the solid patterns 12 are disposed regularly on the substrate body 11. Generally, a plurality of arrangement centers 122 are defined on the substrate body 11 with a regular arrangement. The solid pattern 12 is vertically projected on the substrate body 11 with a projection area 121, and the center of the projection area 121 is just the arrangement center 122. Since the conventional solid pattern 12 is a regular conoid, the projection of the geometric center of the solid pattern 12 on the substrate body 11 is equal to the arrangement center 122 (this is why the geometric center is not shown in FIG. 1A). Besides, the adjacent arrangement centers (or geometric centers) 122 of the conventional solid patterns 12 have the same interval D′.

Although the current electro-optical semiconductor element can generate a considerable amount of electro-optical efficiency, it still can not satisfy the expectation of the industry. However, the electro-optical efficiency of the electro-optical semiconductor element still can be enhanced by changing the embodiment of the solid pattern and the configuration of the substrate body.

Therefore, it is an important subject to provide an electro-optical semiconductor element with enhanced electro-optical efficiency.

### SUMMARY OF THE INVENTION

In view of the foregoing subject, an objective is to provide an electro-optical semiconductor element that can be enhanced in the electro-optical efficiency by the solid patterns having the specific size and arranged with various pitches and spaces.

The solid patterns can have irregular shapes to further enhance the electro-optical efficiency.

To achieve the above objective, a patterned substrate according to the invention comprises a substrate body and a plurality of solid patterns disposed on the substrate body. The pitch of at least a part of the adjacent solid patterns is between 1.5 μm and 2.5 μm, the space of at least a part of the adjacent solid patterns is between 0.1 μm and 0.7 μm, and the height of at least a part of the solid patterns is between 0.7 μm and 1.7 μm. An electro-optical semiconductor element is also disclosed in the invention.

In one embodiment, the solid patterns are disposed by an array arrangement, a staggered arrangement, a honeycomb arrangement, a hexagonal arrangement or a spiral arrangement.

In one embodiment, at least a part of the solid patterns have irregular shapes.

In one embodiment, a geometric center point is formed by the vertical projection of the geometric center of the solid pattern on the substrate body, and at least a part of the geometric center points have different intervals.

In one embodiment, the arrangement center of the solid pattern is different from the corresponding geometric center point.

In one embodiment, the solid pattern has a convex pattern, a concave pattern, or the combination of a convex pattern and a concave pattern.

In one embodiment, a top surface of the solid pattern includes a flat surface and/or curved surface.

In one embodiment, at least a part of the solid patterns are different from the other solid patterns.

In one embodiment, the substrate body includes a sapphire substrate, a silicon substrate, a silicon carbide substrate, a spinel substrate, a polymer substrate, a silica substrate, a silicon nitride substrate, an aluminum nitride substrate, a diamond substrate or a diamond-like carbon substrate.

In one embodiment, the sapphire substrate is a c-plane (0001) sapphire substrate.

To achieve the above objective, an electro-optical semiconductor element according to the invention comprises a patterned substrate and an electro-optical semiconductor unit. The patterned substrate comprises a substrate body and a plurality of solid patterns disposed on the substrate body. The pitch of at least a part of the adjacent solid patterns is between 1.5 μm and 2.5 μm, the space of at least a part of the adjacent solid patterns is between 0.1 μm and 0.7 μm, and the height of at least a part of the solid patterns is between 0.7 μm and 1.7 μm. The electro-optical semiconductor unit is disposed on the patterned substrate.

In one embodiment, the electro-optical semiconductor element is a light emitting diode (LED), an organic light emitting diode (OLED) or a solar cell.

In one embodiment, the electro-optical semiconductor unit includes a first semiconductor layer and a second semiconductor layer sequentially disposed on the patterned substrate.

As mentioned above, because the pitch, space and height of the solid pattern are specified with the specific range of the invention, the patterned substrate can be made more electro-optical efficiency. Besides, the irregular design of the solid pattern can cause more incident angles and emission angles so that the paths of the reflection, refraction and scattering can be increased. Furthermore, when the arrangement center and the geometric center point of the solid pattern are different from each other, the reflective direction of the light will become more diverse so that the paths of the reflection, refraction and scattering can be increased and the electro-optical efficiency can be thus enhanced.

### BRIEF DESCRIPTION OF THE DRAWINGS

The invention will become more fully understood from the detailed description and accompanying drawings, which are given for illustration only, and thus are not limitative of the present invention, and wherein:

FIG. 1A is a partial top view of a conventional patterned substrate;

FIG. 1B is a schematic diagram of a plurality of conventional solid patterns;

FIG. 2A is a schematic top view of a part of a patterned substrate according to a preferred embodiment of the invention;

FIG. 2B is a schematic diagram of the solid patterns in FIG. 2A;

FIGS. 3A to 3D are schematic diagrams of some illustrative variations of the solid pattern according to a preferred embodiment of the invention;

FIG. 4 is an electro-optical semiconductor element according to a preferred embodiment of the invention;

FIG. 5A is a schematic diagram of the comparison between the light emitting efficiencies before the packages of the electro-optical semiconductor elements of the invention and the conventional art; and

FIG. 5B is a schematic diagram of the comparison between the light emitting efficiencies after the packages of the electro-optical semiconductor elements of the invention and the conventional art.

### DETAILED DESCRIPTION OF THE INVENTION

The present invention will be apparent from the following detailed description, which proceeds with reference to the accompanying drawings, wherein the same references relate to the same elements.

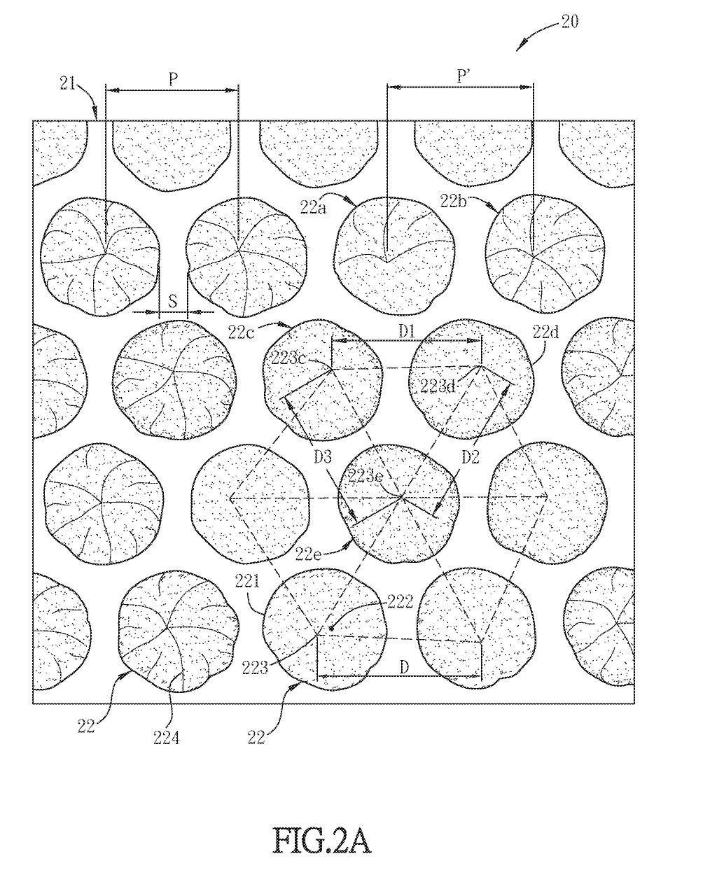

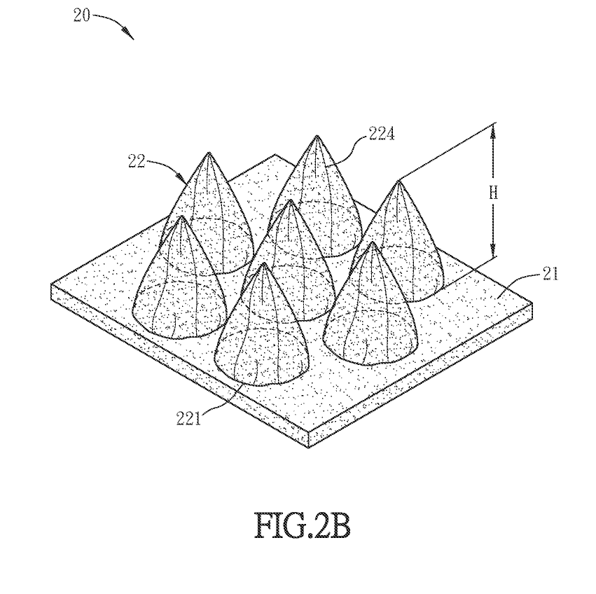

FIG. 2A is a schematic top view of a part of a patterned substrate according to a preferred embodiment of the invention, and FIG. 2B is a schematic diagram of the solid patterns in FIG. 2A. As shown in FIGS. 2A and 2B, the patterned substrate 20 includes a substrate body 21 and a plurality of solid patterns 22 disposed on the substrate body 21. The substrate body 21 can be a sapphire substrate, a silicon substrate, a silicon carbide substrate, a spinel substrate, or a polymer substrate for example. To be noted, the sapphire substrate further can be a c-plane (0001) sapphire substrate. Otherwise, the substrate body 21 can be a silica substrate, a silicon nitride substrate, an aluminum nitride substrate, a diamond substrate or a diamond-like carbon substrate.

FIG. 2A is a top view of the patterned substrate 20, so the solid pattern 22 shown in FIG. 2A is equal to the projection area 221 of the solid pattern projected on the substrate body 21, and accordingly the pitch P and the space S of this embodiment are illustrated as below.

The solid patterns 22 are disposed on the substrate body 21, and a part of the solid patterns have a pitch P between 1.5 μm and 2.5 μm. For example, the pitch of the two adjacent solid patterns is between 1.5 μm and 2.5 μm. To be noted, the solid patterns 22 can have different pitches P.

The pitch P means the largest interval of the two tangent points at which two parallel lines are tangent to the projection area 221 plus the space S between the projection area 221 and the adjacent projection area 221, or the distance D between the geometric centers of the two adjacent solid patterns. In this embodiment, the pitch P is the distance between the geometric centers of the two adjacent solid patterns for example, but the invention is not limited thereto.

For example, as shown in FIG. 2A, two adjacent solid patterns are chosen randomly, such as the solid patterns 22a and 22b, and the distance between the geometric centers of the solid patterns 22a and 22b is the pitch P′. The pitch P′ is between 1.5 μm and 2.5 μm. To be noted, any two pitches are not necessarily the same, and that means the pitches P and P′ may be different, but they are both between 1.5 μm and 2.5 μm.

The space between any two adjacent solid patterns 22 is defined as the space S. At least a part of the solid patterns 22 have the space S between 0.1 μm and 0.7 μm. Besides, as shown in FIG. 2B, at least a part of the solid patterns 22 have a height H between 0.7 μm and 1.7 μm.

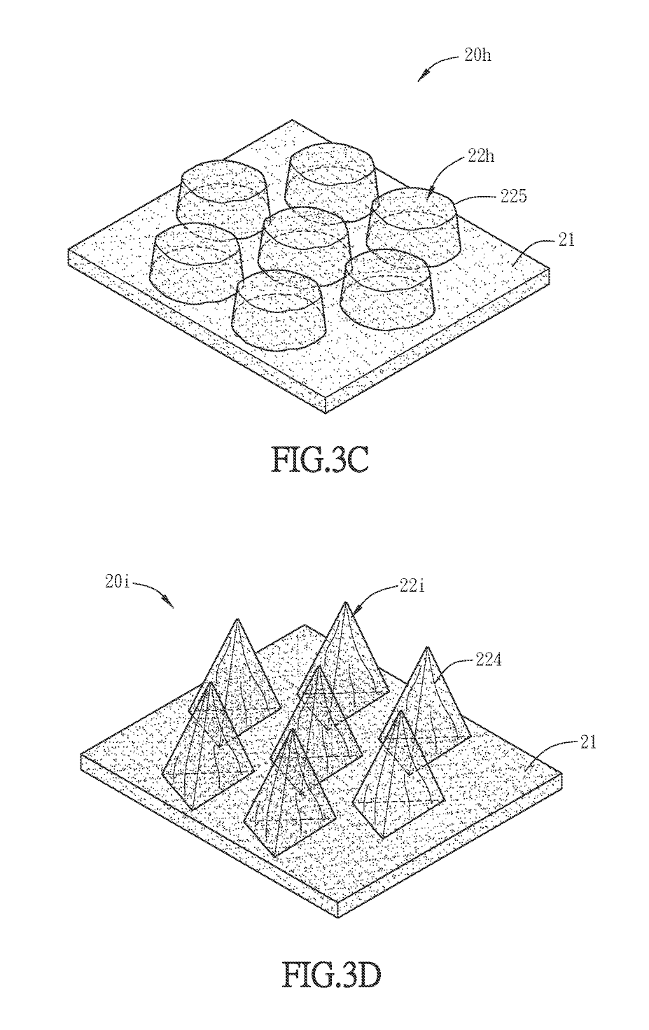

To be noted, the pitches P and spaces S of the adjacent solid patterns 22 and the heights H of the solid patterns 22 can be adjusted under the defined range of the invention, and the solid patterns 22 needn't be the same. According to the defined size of the invention for the solid patterns 22, a patterned substrate 20 of a higher density can be made so as to provide more reflection paths for the light source and the transmittance of the patterned substrate 20 can be thus reduced. Besides, when the patterned substrate of the invention is applied to the electro-optical semiconductor element (as shown in FIG. 4), the patterned substrate having a lower transmittance can make a better reflective effect. Furthermore, because the height H of the solid pattern is less than the conventional art, the epitaxial process can be performed more easily. However, the invention is not limited thereto.

The solid patterns 22 can be disposed on the substrate body 21 by an array arrangement, a staggered arrangement, a honeycomb arrangement, a hexagonal arrangement or a spiral arrangement for example. To be noted, the periodic arrangement is not necessary for the invention, and for example, the pitches P or spaces S of the adjacent solid patterns can be slightly different under the defined condition of the invention. For example, the solid patterns 22 can be disposed by an above-mentioned arrangement (such as an array arrangement or a staggered arrangement) and then adjusted in an irregular way, so that the pitches P or spaces S of the adjacent solid patterns are different. Accordingly, by defining the condition of the size (height H), space (space S) and pitch (pitch P) of the solid patterns 22, the patterned substrate 20 can enhance the electro-optical efficiency.

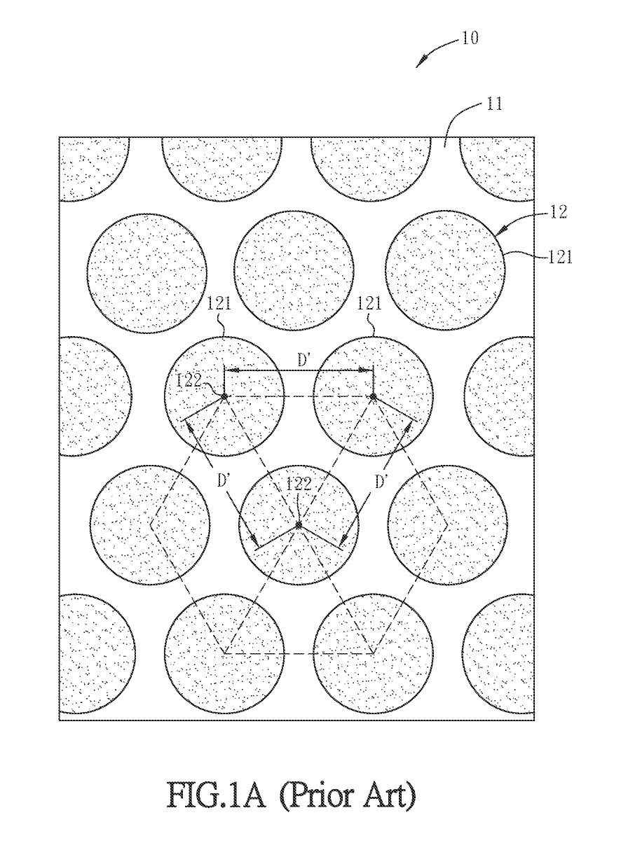

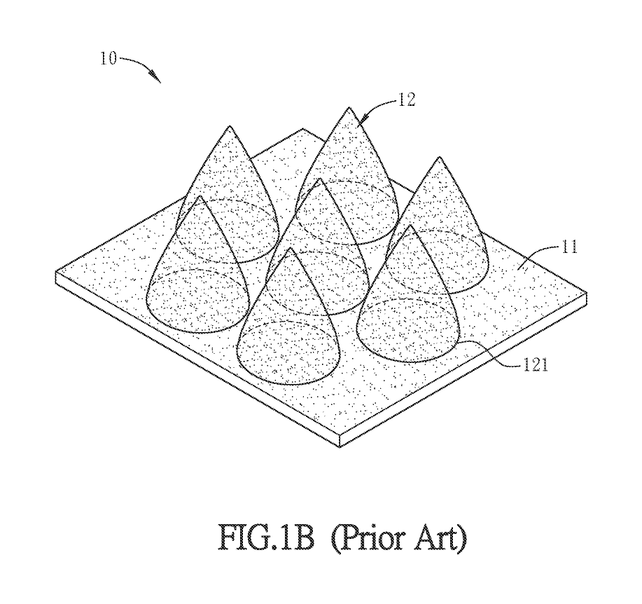

Besides that the solid patterns 22 can be disposed by a regular or irregular arrangement, the solid pattern 22 also can have a regular or irregular shape. The solid pattern 22 of an irregular shape can further enhance the electro-optical efficiency and is regarded as the better case for the invention. As shown in FIGS. 2A and 2B, by referring to the definition of the arrangement center described in the related art, a plurality of arrangement centers 222 (only one arrangement center 222 is shown in FIG. 2A for the clarity of the figure) are defined on the substrate body 21, and the solid patterns 22 are disposed corresponding to the arrangement centers 222 to form the pitches P and spaces S which are defined in the invention as a favorable range. The solid patterns 22 of this embodiment may have irregular shapes, so at least a part of the geometric center points 223 formed by the vertical projection of the geometric centers of the solid patterns on the substrate body 21 are different from the arrangement centers 222, but a part of the geometric center points 223 of the solid patterns 22 may be the same as the arrangement centers 222. To be noted, if the solid patterns have regular shapes, the geometric center points thereof are the same as the arrangement centers (like FIG. 1A).

As shown in FIG. 2A, favorably, at least a part of distances D between the adjacent geometric center points 223 are different. For example, the adjacent solid patterns 22c, 22d, 22e have their geometric center points 223c, 223d, 223e, respectively, the distance D1 is between the geometric center points 223c and 223d, the distance D2 is between the geometric center points 223d and 223e, and the distance D3 is between the geometric center points 223c and 223e. The distances D1˜D3 can be all different as an embodiment, or one of them (such as the distance D1) can be different from the other two (such as the distances D2 and D3) as another embodiment. When the arrangement center 222 and geometric center point 223 of the solid pattern 22 are different from each other, the reflective direction of the light will become more diverse, and therefore the refraction, scattering and reflection can be all increased and the electro-optical efficiency can be thus enhanced.

As shown in FIGS. 2A and 2B, each of the solid patterns 22 has a plurality of ridge lines 224 (for the clarity, some solid patterns 22 are not marked with the ridge lines 224), which are arranged in a radial form and divide the surface of each of the solid patterns 22 into many regions having unequal areas. By such kind of irregular design of the solid pattern 22, incident angles and emission angles can be generated with variety so that the paths of the refraction, scattering and reflection can be all increased and the electro-optical efficiency can be thus enhanced.

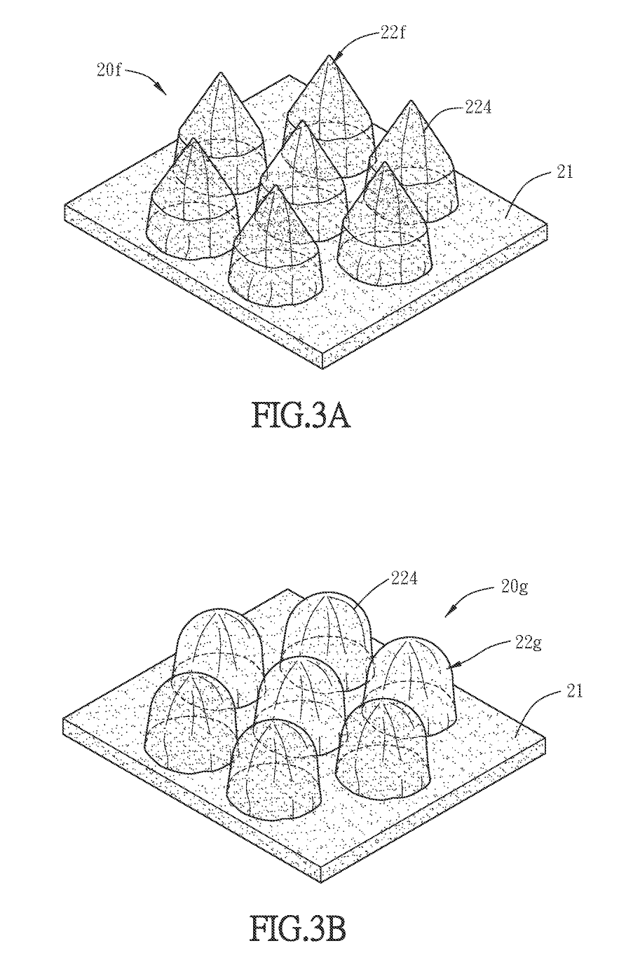

FIGS. 3A to 3D are schematic diagrams of some illustrative variations of the solid pattern according to a preferred embodiment of the invention. As shown in FIGS. 3A to 3D, the top surface of the solid pattern can include a flat surface and/or curved surface, and that means the top surface of the solid pattern can include at least a flat surface, at least a curved surface, or at least a flat surface and at least a curved surface. The said curved surface can be shaped like an acute cone or a smooth camber. The solid pattern 22f in FIG. 3A has a top surface like an acute cone, the solid pattern 22g in FIG. 3B has a top surface like a smooth camber, the solid pattern 22h in FIG. 3C has a top surface like a flat surface, and the solid pattern 22i in FIG. 3D has a top surface like a pyramid. Besides, the surface of the solid pattern 22i in FIG. 3D has a plurality of ridge lines 224 arranged irregularly. In other embodiments, the surface of the solid pattern 22i also can include a flat side of a single slope, or a curved side such as having a parabolic curve. However, the invention is not limited thereto, as long as the variation conforms to that the pitch of at least a part of the solid patterns is between 1.5 μm and 2.5 μm, the space of at least a part of the adjacent solid patterns is between 0.1 μm and 0.7 μm, the height H of at least a part of the solid patterns is between 0.7 μm and 1.7 μm, and at least a part of the solid patterns have irregular shapes.

Not only the solid pattern 22 has an irregular shape, but also at least a part of the solid patterns 22 may have different shapes from the other solid patterns 22. The solid pattern 22 can have a convex pattern, a concave pattern, or the combination of a convex pattern and a concave pattern. By the irregular shapes of the solid patterns, the incident angle of the light will be unequal to the emission angle, and this will increase the refraction, scattering and reflection so that the moving directions of the light will become more diverse and the electro-optical efficiency can be thus enhanced.

The below is the demonstration by the experimental data that the electro-optical efficiency of the invention is better than the conventional art.

For the conventional solid pattern, the diameter thereof is about 2.4 μm, the space thereof is about 0.6 μm, and the height thereof is about 1.5 μm, and thus a surface of a 2 square inches patterned substrate can be configured with about 2.6 hundred millions of solid patterns.

According to the solid pattern of the invention, for example, the largest interval of the two tangent points at which two parallel lines are tangent to the projection area is about 1.6 μm, the space thereof is about 0.4 μm, and the height thereof is about 1.1 μm, and thus a surface of a 2 square inches patterned substrate can be configured with about 5.8 hundred millions of solid patterns. To be noted, the solid patterns are also arranged irregularly with one of the above-mentioned arrangements, for example.

Besides, when the ratio of the total surface area (i.e. the sum of the total surface area of all the solid patterns on the substrate body to the area of the substrate body), in the above-mentioned conventional case with the dimensions of the solid pattern (2.4*0.6*1.5) and the number of the solid patterns (about 2.6 hundred millions), is regarded as 100% as the base, the ratio of the total surface area in the above-mentioned case of the invention with the dimensions of the solid pattern (1.6*0.4*1.1) and the number of the solid patterns (about 5.8 hundred millions), achieves 133.6% by an increment of 33.6%. Accordingly, under the same area of the substrate body, the substrate body of the invention can be configured with more solid patterns with the specific size range so that the ratio of the total surface area can be increased, and therefore the more paths of the reflection, refraction and scattering can be generated and the electro-optical efficiency can be thus enhanced. To be noted, the case with the dimensions of the solid pattern (1.6*0.4*1.1) and the number of the solid patterns (about 5.8 hundred millions) is just for example but not for limiting the scope of the invention.

FIG. 4 is an electro-optical semiconductor element according to a preferred embodiment of the invention. As shown in FIG. 4, the electro-optical semiconductor element 3 can be a light emitting diode (LED), an organic light emitting diode (OLED) or a solar cell. In this embodiment, the electro-optical semiconductor element 3 is an LED for example, but the invention is not limited thereto.

The electro-optical semiconductor element 3 includes a patterned substrate 31 and an electro-optical semiconductor unit 32 disposed on the patterned substrate 31. The electro-optical semiconductor unit 32 includes a first semiconductor layer 321 and a second semiconductor layer 322 sequentially disposed on the patterned substrate 31. The patterned substrate 31 has a plurality of solid patterns 311 arranged irregularly, and the solid patterns 311 are irregular three-dimensional structures. The technical features of the patterned substrate 31 with the solid patterns 311 are clearly illustrated in the above embodiments, and therefore they are not described here for conciseness.

In this embodiment, the electro-optical semiconductor unit 32 further includes a light emitting layer 323, which is disposed between the first and second semiconductor layers 321 and 322. The first semiconductor layer 321 is disposed on the patterned substrate 31, the light emitting layer 323 is disposed on the first semiconductor layer 321, and the second semiconductor layer 322 is disposed on the light emitting layer 323. The first semiconductor layer 321 is a p-type semiconductor layer and the second semiconductor layer 322 is an n-type semiconductor layer, or the first semiconductor layer 321 is an n-type semiconductor layer and the second semiconductor layer 322 is a p-type semiconductor layer. The electro-optical semiconductor unit 32 composed of the first semiconductor layer 321, the light emitting layer 323 and the second semiconductor layer 322 can be a light-emitting epitaxial structure.

The electro-optical semiconductor element 3 of this embodiment further includes a contact layer 33, a first electrode 34 and a second electrode 35. The contact layer 33 is disposed on the second semiconductor layer 322, the first electrode 34 is disposed on the contact layer 33, and the second electrode 35 is disposed on the first semiconductor layer 321 and corresponding to the first electrode 34. When the current is provided, the light is generated and reflected by the patterned substrate 31 to leave the electro-optical semiconductor element 3. Accordingly, the reflectivity of the light is closely related to the light emitting efficiency of the electro-optical semiconductor element 3.

Herein, the above-mentioned case of the invention (the dimensions (1.6*0.4*1.1) of the solid pattern and about 5.8 hundred millions of the solid patterns) and the above-mentioned case of the conventional art (with the dimensions (2.4*0.6*1.5) of the solid pattern and about 2.6 hundred millions of the solid patterns) are applied to the electro-optical semiconductor element 3 as the patterned substrate 31 with the solid patterns 311, and their light emitting efficiencies before and after the package are compared with each other as below.

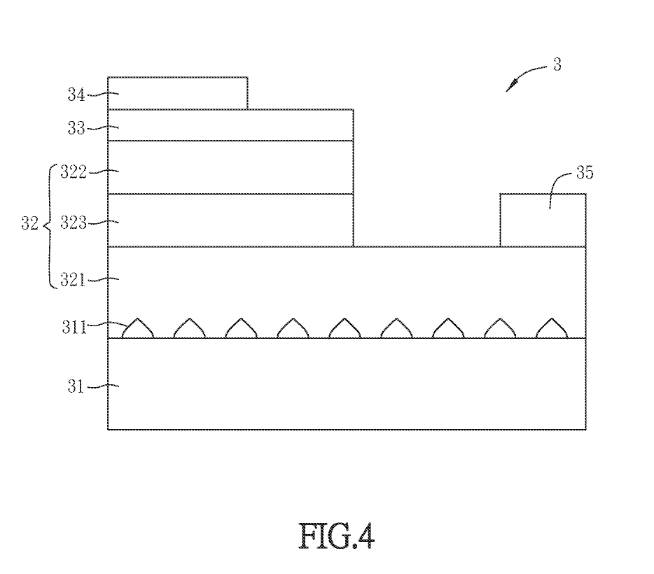

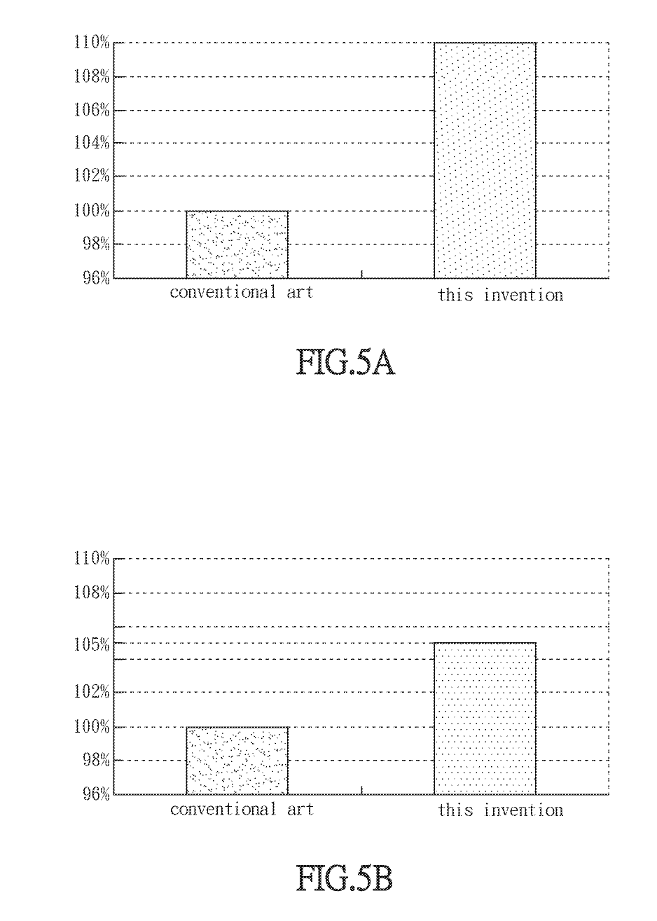

FIG. 5A is a schematic diagram of the comparison between the light emitting efficiencies before the packages of the electro-optical semiconductor elements of the invention and the conventional art. When the light emitting efficiency of the electro-optical semiconductor element in the case of the conventional art (with the dimensions (2.4*0.6*1.5) of the solid pattern and about 2.6 hundred millions of the solid patterns) is regarded as 100% as the base, the light emitting efficiency of the electro-optical semiconductor element in the case of the invention (with the dimensions (1.6*0.4*1.1) of the solid pattern and about 5.8 hundred millions of the solid patterns) can achieve 110%. Accordingly, it is obvious that the electro-optical efficiency of the invention is better than the conventional art.

FIG. 5B is a schematic diagram of the comparison between the light emitting efficiencies after the packages of the electro-optical semiconductor elements of the invention and the conventional art. Likewise, when the light emitting efficiency of the electro-optical semiconductor element in the case of the conventional art is regarded as 100% as the base, the light emitting efficiency of the electro-optical semiconductor element in the case of the invention can achieve 105%. Accordingly, it is still obvious that the electro-optical efficiency of the invention is better than the conventional art.

The result is generated because the pitch, space and height of the solid pattern is specified with the specific range of the invention and therefore the solid patterns are arranged on the substrate body irregularly, so that the paths of the reflection, refraction and scattering are increased and the electro-optical efficiency of the electro-optical semiconductor element can be thus enhanced.

Additionally, when the surface of the solid pattern has an irregular shape, the electro-optical efficiencies of the patterned substrate and electro-optical semiconductor element can be further enhanced.

In summary, because the pitch, space and height of the solid pattern are specified with the specific range of the invention, the patterned substrate can be made more electro-optical efficiency. Besides, the irregular design of the solid pattern can cause more incident angles and emission angles so that the paths of the reflection, refraction and scattering can be increased. Furthermore, when the arrangement center and the geometric center point of the solid pattern are different from each other, the reflective direction of the light will become more diverse so that the paths of the reflection, refraction and scattering can be increased and the electro-optical efficiency can be thus enhanced.

Although the invention has been described with reference to specific embodiments, this description is not meant to be construed in a limiting sense. Various modifications of the disclosed embodiments, as well as alternative embodiments, will be apparent to persons skilled in the art. It is, therefore, contemplated that the appended claims will cover all modifications that fall within the true scope of the invention.

What is claimed is:

1. A patterned substrate, comprising:
a substrate body; and
a plurality of solid patterns disposed on the substrate body,
wherein the pitch of at least a part of the adjacent solid patterns is between 1.5 μm and 2.5 μm, the space of at least a part of the adjacent solid patterns is between 0.1 μm and 0.7 μm, and the height of at least a part of the solid patterns is between 0.7 μm and 1.7 μm.

2. The patterned substrate as recited in claim 1, wherein the solid patterns are disposed by an array arrangement, a staggered arrangement, a honeycomb arrangement, a hexagonal arrangement or a spiral arrangement.

3. The patterned substrate as recited in claim 1, wherein at least a part of the solid patterns have irregular shapes.

4. The patterned substrate as recited in claim 1, wherein a geometric center point is formed by the vertical projection of the geometric center of the solid pattern on the substrate body, and at least a part of the geometric center points have different intervals.

5. The patterned substrate as recited in claim 4, wherein the arrangement center of the solid pattern is different from the corresponding geometric center point.

6. The patterned substrate as recited in claim 1, wherein the solid pattern has a convex pattern, a concave pattern, or the combination of a convex pattern and a concave pattern.

7. The patterned substrate as recited in claim 1, wherein a top surface of the solid pattern includes a flat surface and/or curved surface.

8. The patterned substrate as recited in claim 1, wherein at least a part of the solid patterns are different from the other solid patterns.

9. The patterned substrate as recited in claim 1, wherein the substrate body includes a sapphire substrate, a silicon substrate, a silicon carbide substrate, a spinel substrate, a polymer substrate, a silica substrate, a silicon nitride substrate, an aluminum nitride substrate, a diamond substrate or a diamond-like carbon substrate.

10. The patterned substrate as recited in claim 9, wherein the sapphire substrate is a c-plane (0001) sapphire substrate.

11. An electro-optical semiconductor element, comprising:
a patterned substrate, comprising:
a substrate body; and
a plurality of solid patterns disposed on the substrate body, wherein the pitch of at least a part of the adjacent solid patterns is between 1.5 μm and 2.5 μm, the space of at least a part of the adjacent solid patterns is between 0.1 μm and 0.7 μm, and the height of at least a part of the solid patterns is between 0.7 μm and 1.7 μm; and
an electro-optical semiconductor unit disposed on the patterned substrate.

12. The electro-optical semiconductor element as recited in claim 11, wherein the solid patterns are disposed by an array arrangement, a staggered arrangement, a honeycomb arrangement, a hexagonal arrangement or a spiral arrangement.

13. The electro-optical semiconductor element as recited in claim 11, wherein at least a part of the solid patterns have irregular shapes.

14. The electro-optical semiconductor element as recited in claim 11, wherein a geometric center point is formed by the vertical projection of the geometric center of the solid pattern on the substrate body, and at least a part of the geometric center points have different intervals.

15. The electro-optical semiconductor element as recited in claim 14, wherein the arrangement center of the solid pattern is different from the corresponding geometric center point.

16. The electro-optical semiconductor element as recited in claim 11, wherein the solid pattern has a convex pattern, a concave pattern, or the combination of a convex pattern and a concave pattern.

17. The electro-optical semiconductor element as recited in claim 11, wherein a top surface of the solid pattern includes a flat surface and/or curved surface.

18. The electro-optical semiconductor element as recited in claim 11, wherein at least a part of the solid patterns are different from the other solid patterns.

19. The electro-optical semiconductor element as recited in claim 11, which is a light emitting diode (LED), an organic light emitting diode (OLED) or a solar cell.

20. The electro-optical semiconductor element as recited in claim 11, wherein the electro-optical semiconductor unit includes a first semiconductor layer and a second semiconductor layer sequentially disposed on the patterned substrate.
